(19) United States
(12) Patent Application Publication
(10) Pub. No.: US 2014/0017479 A1
(43) Pub. Date: Jan. 16, 2014

(54) METHOD OF FORMING AN R-PLANE SAPPHIRE CRYSTAL

(71) Applicants: Guilford L. Mack, III, Manchester, NH (US); Christopher D. Jones, Amherst, NH (US); Fery Pranadi, Nashua, NH (US); John Walter Locher, Amherst, NH (US); Steven Anthony Zanella, Dublin, NH (US); Herbert Ellsworth Bates, Amherst, NH (US)

(72) Inventors: Guilford L. Mack, III, Manchester, NH (US); Christopher D. Jones, Amherst, NH (US); Fery Pranadi, Nashua, NH (US); John Walter Locher, Amherst, NH (US); Steven Anthony Zanella, Dublin, NH (US); Herbert Ellsworth Bates, Amherst, NH (US)

(21) Appl. No.: 14/031,848

(22) Filed: Sep. 19, 2013

Related U.S. Application Data
(62) Division of application No. 12/274,593, filed on Nov. 20, 2008.
(60) Provisional application No. 60/989,756, filed on Nov. 21, 2007.

(51) Int. Cl. C30B 15/20; C30B 29/22; C30B 15/34

(52) U.S. Cl. CPC C30B 15/203; C30B 15/34; C30B 29/22
USPC 428/220; 117/13; 117/26

(57) ABSTRACT

A method and apparatus for the production of r-plane single crystal sapphire is disclosed. The method and apparatus may use edge defined film-fed growth techniques for the production of single crystal material exhibiting an absence of lineage.

### RELATED APPLICATIONS

This application claims priority under 35 U.S.C. §120 to U.S. patent application Ser. No. 12/274,593 entitled “R-Plane Sapphire Method and Apparatus” by Mack, III et al. filed Nov. 20, 2008, which claims priority under 35 U.S.C. §119(e) to U.S. Patent Application 60/989,756 entitled “R-Plane Sapphire Method and Apparatus” by Mack, III et al. filed Nov. 21, 2007, all of which are assigned to the current assignee hereof and incorporated herein by reference in their entireties.

### BACKGROUND

1. Field of Invention

The invention relates to ceramics and methods of production and, in particular, to r-plane single crystal sapphire and methods of making r-plane single crystal sapphire.

2. Discussion of Related Art

Single crystal sapphire, or α-alumina, is a ceramic material having properties that make it attractive for use in a number of fields. For example, single crystal sapphire is hard, transparent and heat resistant, making it useful in, for example, optical, electronic, armor and crystal growth applications. Due to the crystalline structure of single crystal sapphire, sapphire sheets may be formed in various planar orientations including C-plane, m-plane, r-plane and a-plane. Different planar orientations may yield different properties that provide for different utility. For example, r-plane wafers may be used in the production of semiconductors and may be particularly useful in the production of silicon on sapphire (SOS) products. For example, see U.S. Pat. No. 5,416,043 titled “Minimum charge FET fabricated on an ultrathin silicon on sapphire wafer.”

Several techniques for the production of single crystal sapphire are known including the Kyropolos, Czochralski, Horizontal Bridgman, Verneuile technique, heat exchange, and shaped crystal growth techniques such as edge defined film-fed growth methods.

### SUMMARY OF INVENTION

The subject matter of this application may involve, in some cases, interrelated products, alternative solutions to a particular problem, and/or a plurality of different uses of a single system or article.

In one aspect, an r-plane single crystal sapphire wafer is provided, the wafer having a diameter greater than or equal to 200 mm.

In another aspect, a single crystal sapphire ribbon is provided, the ribbon having essentially r-plane orientation and a width of greater than or equal to 150 mm and exhibiting no detectable lineage.

In another aspect, a method of forming the spread of an r-plane single crystal sapphire ribbon is provided, the method comprising

seeding a crystal melt in an r-plane orientation, pulling the seed to form the spread, and controlling the weight gain of the crystal during the time period from when the spread increases in width from 0.5 inch to full width by limiting the rate of weight gain during any 1 inch pull length increment to less than double the rate of weight gain for the previous 1 inch pull length increment.

In another aspect a method of forming the spread of an r-plane single crystal sapphire ribbon is provided where y is the rate of weight gain, x is the pull length of the crystal and a and b are constants. The method comprises pulling the crystal from a pull length of 0.5 inch to full spread width wherein the rate of weight gain during this period fits the equation y=ax^{b} and the r² value over this range is at least 0.95.

In another aspect an apparatus for producing single crystal sapphire is provided, the apparatus comprising a melt source, a die in fluid communication with the melt source, the die being in a first active heat zone, an insulated chimney mounted above the die, the chimney defining an open top and including a second independently controllable heat zone, and an insulated door mounted on the top of the chimney wherein the door encloses at least 50% of the area of the open top and is constructed and arranged to open when a sapphire ribbon is pulled upwardly through the open top.

In another aspect, a method of producing a lineage-free r-plane sapphire ribbon is provided, the method comprising seeding a melt fixture with a seed having an r-plane orientation substantially parallel to a longitudinal axis of a die opening and parallel to the direction of crystal growth, crystallizing single crystal sapphire above the die at a melt interface, and forming a spread at a rate in which the rate of weight gain of the crystal is less than 80% of the maximum rate of weight gain.

In another aspect a method of forming r-plane single crystal sapphire is provided, the method comprising seeding a melt fixture with a seed having an r-plane orientation substantially parallel to the longitudinal axis of the die opening and to the direction of crystal growth, crystallizing single crystal sapphire above the die, the single crystal sapphire exhibiting an r-axis orientation substantially perpendicular to the sapphire's major surface, passing the single crystal sapphire through a first region exhibiting a first thermal gradient of less than about 65° C./in, and subsequently passing the sapphire through a second region exhibiting a second thermal gradient of less than about 16° C./in wherein the first region is within one half inch of the die tip and has a length of less than about 3 inches and the second region is adjacent to the first region.

In another aspect, a method of producing a single crystal r-plane sapphire ribbon is provided, the method comprising seeding a melt fixture with a seed having an r-plane orientation substantially parallel to the longitudinal axis of the die opening and to the direction of crystal growth, increasing the width of the ribbon during the spread from 0.5 inch to full width by controlling the rate of weight gain at less than 80% of the maximum rate of weight gain, and pulling a portion of the ribbon from a die tip to a height of 1 inch above the die tip while subjecting the portion of the ribbon to a temperature decrease of less than 30 degrees Celsius.

In another aspect, a method of producing a single crystal r-plane sapphire ribbon is provided, the method comprising seeding a melt fixture with a seed having an r-plane orientation substantially parallel to the longitudinal axis of the die opening and to the direction of crystal growth, increasing the width of the ribbon during the spread from 0.5 inch to full width by controlling the rate of weight gain at less than 80% of the maximum rate of weight gain, and drawing the ribbon from the die tip for at least one hour while subjecting the ribbon to a temperature decrease of less than 30 degrees Celsius.

### BRIEF DESCRIPTION OF DRAWINGS

In the drawings,

FIG. 1 is a diagram illustrating the crystal orientation of an a-plane single crystalline material;

FIG. 2 is a diagram illustrating the crystal orientation of an r-plane single crystalline material;

FIG. 3 is a cutaway view of one embodiment of an apparatus for producing r-plane single crystal sapphire;

FIG. 4 is a photocopy of an x-ray topograph showing lineage in an r-plane ribbon;

FIG. 5 is a photocopy of an x-ray topograph showing an absence of lineage in a different r-plane ribbon;

FIG. 6 is a graphical representation of a temperature profile in one embodiment of an apparatus for producing single crystal sapphire;

FIG. 7 is a graphical representation of a temperature profile in one embodiment of an apparatus for producing single crystal sapphire;

FIG. 8 is a graphical representation of a temperature profile in one embodiment of an apparatus for producing r-plane single crystal sapphire;

FIG. 9 is a photograph showing the edges of two r-plane single crystal sapphire ribbons;

FIG. 10 is a graphical representation showing a maximum rate of weight gain during the spread; and

FIG. 11 is a graphical representation showing a controlled rate of weight gain during the spread.

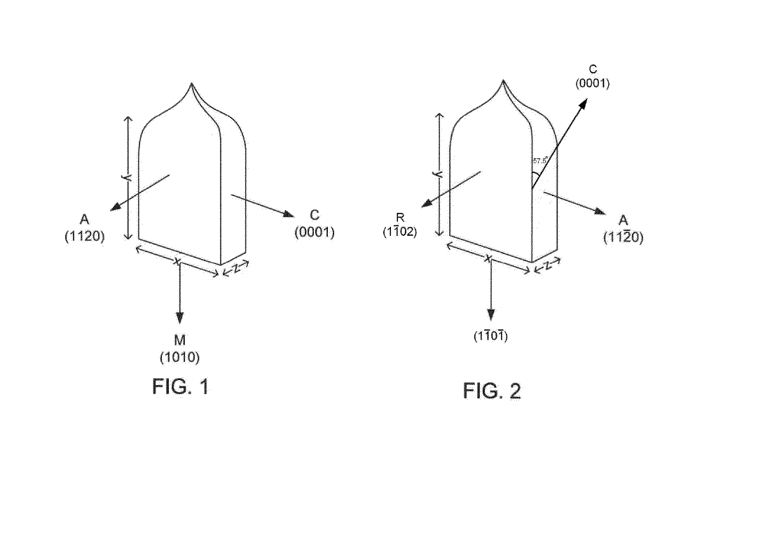

### DETAILED DESCRIPTION

The materials and methods described in this disclosure include r-plane single crystal sapphire and methods and apparatuses for producing r-plane sapphire. R-plane sapphire may be used in a variety of applications, for example, as a substrate on which to grow SOS chips.

Edge defined film-fed growth (EFG) techniques have been used to grow single crystal sapphire in several planar configurations including a-plane and C-plane. For example, see U.S. patent application Ser. No. 11/858,949 filed on Sep. 21, 2007, titled “C-PLANE SAPPHIRE METHOD AND APPARATUS” which is hereby incorporated by reference herein.

In one aspect, the invention includes a method and apparatus that define a new EFG method to produce r-plane single crystal sapphire that is essentially free of lineage. The resulting ribbons may exhibit increased width and length compared to existing techniques. The size limitations inherent in wafers formed from boules using methods such as Kyropolos and Czochralski may be bypassed and wafers may be cut from the resulting ribbons in diameters of greater than 15 cm, greater than 20 cm and greater than 25 cm. A wafer may not be entirely round and can include one or more notches or flat portions that may be used, for example, for orientation of the wafer. As used herein, the diameter of a wafer is the largest dimension across the wafer from edge to edge and should not be measured from a notch or flat.

In another aspect, r-plane sapphire ribbons, or sheets, may be grown in an apparatus that provides for controlled cooling of the ribbons. Cooling rates may be reduced, for example, by reducing heat loss from the ribbon through the addition of insulated doors and the reduction in the size of viewports. In other embodiments, defects may be reduced by adding weight to the spread of the ribbon at a controlled rate.

“Single Crystal Sapphire” means α-Al₂O₃, also known as corundum that is primarily single crystal.

“R-plane single crystal sapphire” refers to substantially planar single crystal sapphire, the r-axis of which is substantially normal (+/−10 degrees, usually +/−1 degree) to the major planar surface of the material. See FIG. 2. The “sapphire r-plane” is as is known in the art and is one of the three sapphire planes [1-102] [-1012], and [01-12].

“Dislocation” is used herein as it is used by those skilled in the art and describes a crystal defect that can be detected using X-ray diffraction topography based on Bragg diffraction.

“Lineage” is a form of polycrystallinity and is a grain (or grains) within a crystal that has a low angle of misorientation with respect to the direction of growth. This angle of misorientation is typically less than 2 degrees but can be greater. Lineage is a form of polycrystallinity that is usually restrained in columns or lines that travel the length, or most of the length, of a crystal. Under some conditions, lineage may become less organized and may break down into general polycrystallinity A crystal exhibiting lineage is typically less desirable in many applications, especially when used for chip fabrication or when the sapphire is used as a substrate or template for crystal growth. Lineage can be detected using x-ray topography.

The “spread” of a crystal ribbon is a term known to those of skill in the art and is the first portion of a ribbon that is formed prior to the ribbon reaching full width. It typically starts with a narrow portion at the seed and increases in width until full width is reached.

“Thermal gradient” refers to the average change in temperature over distance between two locations in a single crystal sapphire production apparatus. The distance between the two locations is measured on a line along which the single crystal sapphire advances during the production process. For example, in an edge defined film-fed growth technique, the temperature difference may be 50 degrees Celsius between a first position in the furnace and a second position in the furnace. Thermal gradient units may be, for example, “degrees per cm” or “degrees per inch.” If not specified, the temperature change is from a higher temperature to a lower temperature as the sapphire crystal passes from the first location to the second through the gradient.

“Ribbon” refers to a plate formed using a shaped crystal growth technique.

It has been shown that uniform a-plane sheets of single crystal sapphire can be produced efficiently using edge defined film-fed growth techniques (see U.S. Patent Application Publication 2005/0227117). However, r-plane sheets are typically sliced from a boule that is grown along different growth orientation using, for example, the Czochralski method. Boules can have various shapes and can be oriented so that there are different orientations of r-axis in different boules. For making wafers, cylinders of the desired diameters can be cored from boules and the desired wafers may be cut from the cylinders, for instance by using a wire saw slicing through the diameter of the cylinder. After cutting, the slice is typically ground and polished to produce an r-plane wafer. Wafer thicknesses may be chosen by first cutting the slice to a pre-chosen width and then lapping to the desired dimensions. Using this method of production to form a plate or wafer from a boule, each sheet or wafer must be cut along its major planar surface at least once. The extreme hardness of single crystal sapphire means that the cutting step may be expensive and time consuming. Additional preparation steps may also be required. Furthermore, the production of larger size wafers, e.g., greater than or equal to 5 or 10 cm in diameter, may take weeks due to, in part, the secondary and tertiary operations.

R-plane single crystal sapphire formed in sheets or ribbons could reduce or shorten many of these preparation steps. For this reason and others, r-plane sheets exhibiting good optical characteristics and low lineage could provide a preferred source for r-plane single crystal sapphire.

R-plane ribbons can be made using the EFG techniques for C-plane material as described in U.S. patent application Ser. No. 11/858,949 titled C-PLANE SAPPHIRE METHOD AND APPARATUS. Under visible light these ribbons appear to be defect free. However, x-ray topography reveals extensive lineage that travels the length of the ribbon. See FIG. 2.

In one embodiment, r-plane single crystal sapphire ribbons showing an absence of lineage can be grown using a shaped crystal growth technique that includes passing the ribbon through two or more cooling regions in which the cooling rate is specifically controlled.

R-plane ribbons grown using conventional EFG techniques often appear to be perfect crystals that would be appropriate for the production of SOS chips. However, wafers grown by this technique have been found to be unsuitable for the production of SOS chips. It has been found after x-ray topographic analysis of the ribbons that the ribbons contain extensive lineage. Furthermore, it is believed that this lineage is what makes the wafers unsuitable for SOS chip production. Therefore a method to produce lineage-free r-plane single crystal sapphire would be a great improvement over the current state of the art.

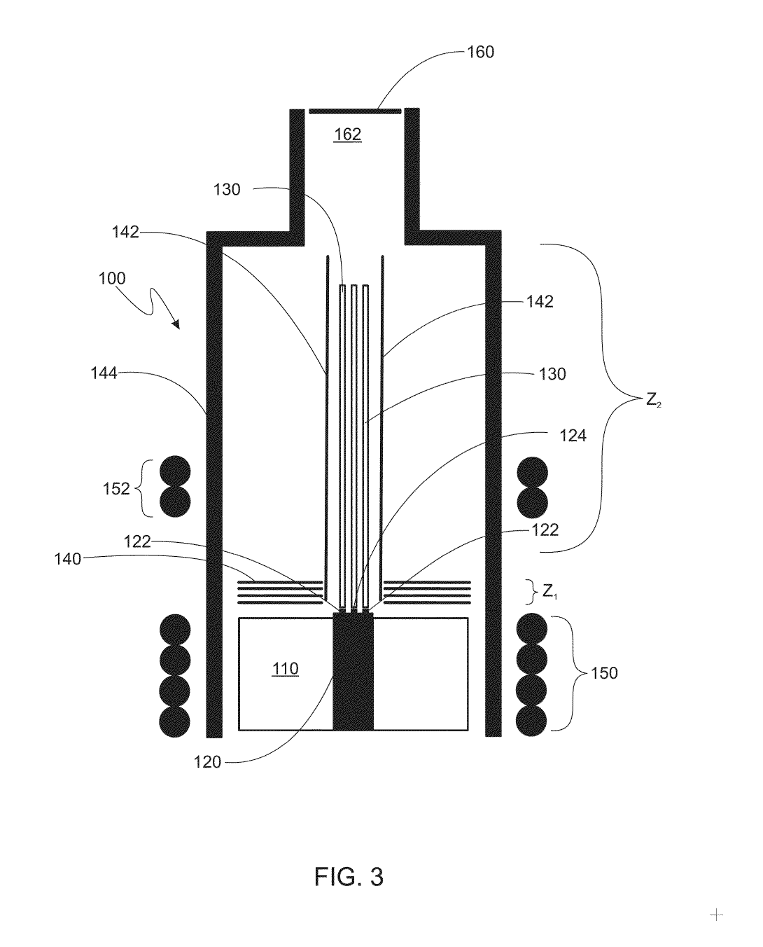

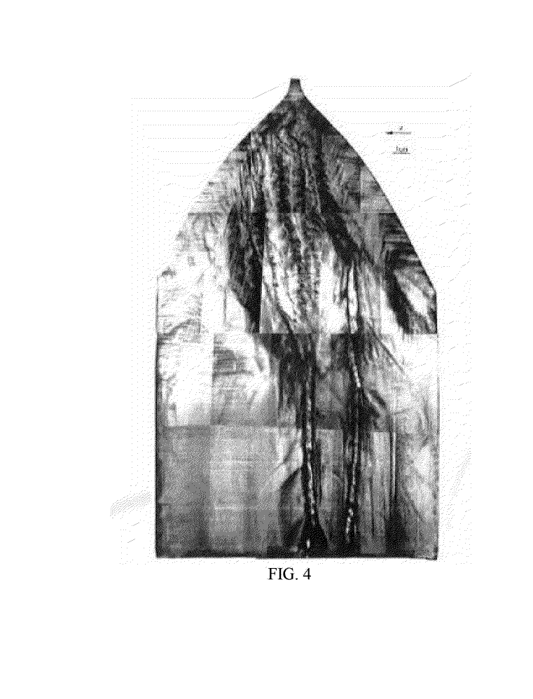

FIG. 3 provides a cross sectional view of an apparatus 100 used to produce r-plane ribbons. Insulating heater 144 may be made of a heat resistant material such as graphite that couples or partially couples with RF field caused by induction coils 150 and 152. The apparatus includes a melt source such as crucible 110 for holding a melt that may be molten Al₂O₃. Heat may be generated in both enclosure 144 and in the crucible 110. The crucible may be made of any material capable of containing the melt. Alumina may be fed to the crucible on a batch or continuous basis. Suitable materials for crucible construction include, for example, iridium, molybdenum, tungsten or molybdenum/tungsten alloys. Molybdenum/tungsten alloys may vary in composition from 0 to 100% molybdenum. Capillary die 120 is in fluid contact with the melt and includes 3 die tips from which melt can be drawn. Although three die tips are shown, any number may be used. Outer die tips 122 and inner die tip 124 each include openings through which ribbons 130 may be concurrently drawn. Outer die tips 122 may be positioned about 0.020 inches higher than inner die tip 124. This offset may help to equalize the temperature profile that each die tip and ribbon is exposed to. A die tip as shown in FIG. 3 is typically warmer at its edges than in a central portion. It is believed that a significant portion of the heat is lost via radiation channeling through the ribbon as it is formed. Thus, the wider the ribbon, the more heat may be lost through this mechanism.

The view shown in FIG. 3 is an end view illustrating the thickness of each ribbon. Thickness of the ribbon is based, at least in part, on the width of the die tip. From left to right in FIG. 3, the depth (the shortest dimension of the die tip) of the die tip may be chosen to determine the thickness of the ribbon that is produced. The die depth may be, for instance, about 0.1, 0.2, 0.5 or 1.0 centimeters, or greater. The width (the view in FIG. 3 is looking along the width of the die tip) of the die determines the width of the ribbon and may be, for example, 10 cm, 15 cm, 20 cm, 25 cm or greater. Thus, a die tip having a depth of 0.5 cm and a width of 20 cm would produce ribbons approximately 0.5 cm thick and approximately 20 cm wide. The dimensions of the die tip are independent of the dimensions of the capillary opening that feeds the melt to the die tip. The length of the ribbon that can be drawn is limited by practical considerations such as space requirements and ease of handling. Unless otherwise specified the length of a ribbon is measured from the neck (narrow point where the ribbon is seeded) to the opposing end.

As crystallization occurs, heat may be lost from the sapphire ribbons through conduction, convection and radiation. Heat can be supplied to the system by, for example, inductively coupling heater 144 and crucible 110 or by resistively heating the system. Heat shields 140 are positioned in heat zone 1 (z1) and can help to reduce the heat loss from the ribbons as they start to radiate after formation. Insulating container 142 may be designed to help reduce heat loss from the ribbons. The container may be made of a high temperature material, such as molybdenum, that can be inductively coupled to upper rf induction coil 152 to provide heat to zone 2 (z2). In zone 1, heat shields 140 and insulating container may help to reduce heat loss in the region where the ribbons are at their highest temperature. RF induction coils 150 and 152 may or may not be a continuous coil. RF induction coils 150 and 152 may be two separate coils and be independently controlled.

Door 160 covers at least a portion of opening 162 at the top of the enclosure and may reduce heat loss and may direct gas flow, resulting in altering the thermal gradient. An inert gas, such as argon, is typically flowed into the apparatus to help limit oxidation. This gas flow can remove heat from the system and a reduction in the amount of gas flow will also reduce the amount of heat lost from the system. Door 160 may prevent the loss of heat that would otherwise be lost through radiation or convection. The door may be a single door or a double trap door, for example, and may be hinged so that it can open to allow the passage of ribbons as they are pulled upwardly through opening 162. In some embodiments, the door may enclose, or be adjusted to enclose, greater than 50%, greater than 75%, or greater than 90% of the opening area.

EFG apparatus 100 can be equipped with two viewports positioned to allow visual monitoring of the formation of the ribbons at the die tips. These viewports may be about 0.22×0.66 inches in size. However, it has been found that a reduction in viewport size to about 0.15×0.75 inches can provide a significant reduction in heat loss, resulting in better control of temperature gradients.

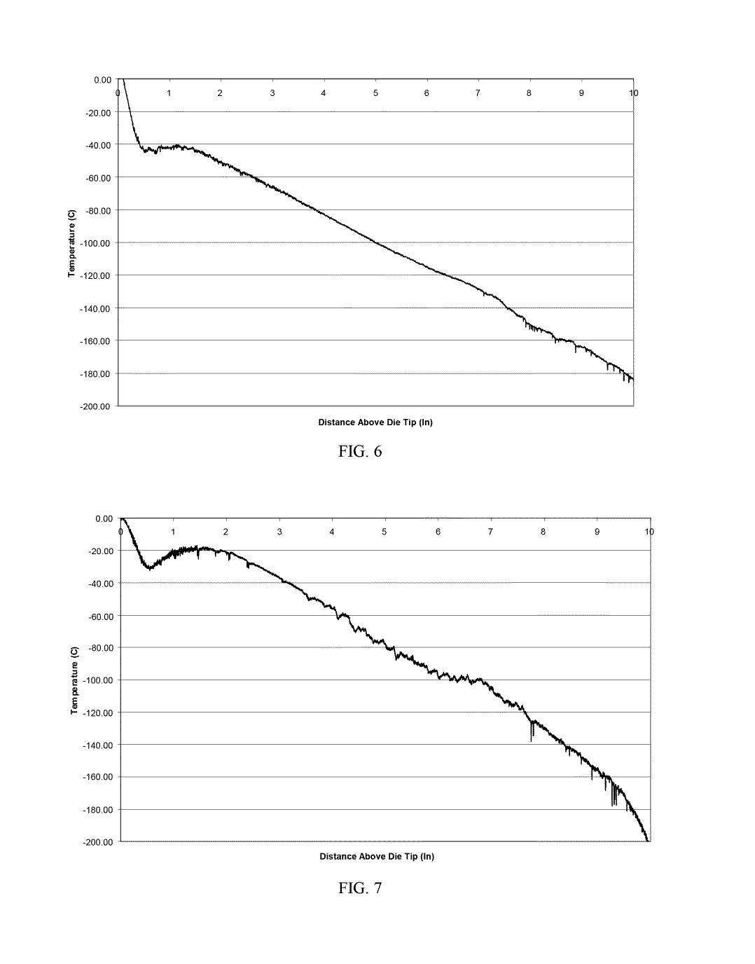

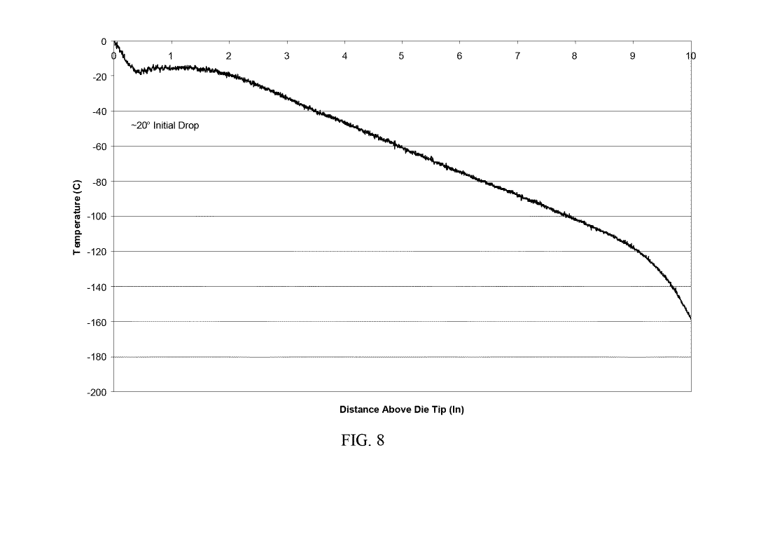

A comparison of the heat lost with and without these changes is shown in FIGS. 6, 7 and 8. FIG. 6 provides a graphical representation of the vertical temperature gradient in an apparatus (A) that lacks an active second stage heat source and includes standard sized viewports as well as an open top. FIG. 7 provides a graphical representation of the vertical temperature gradient in an apparatus (B) that uses an active second stage heat source and includes standard sized viewports as well as an open top. FIG. 8 provides a graphical representation of the vertical temperature gradient in an improved apparatus (C) with smaller viewports and a pivotable trap door covering the opening at the top of the chimney (see FIG. 3). Temperature measurements were taken using a thermocouple under conditions simulating ribbon growth but without ribbons actually being drawn.

FIG. 6 shows an initial drop of more than 40 degrees Celsius between the die tip and the first half inch above the die tip in apparatus A. FIG. 7, which provides results from apparatus B with the second stage heat source, shows an initial drop of about 30 degrees Celsius between the die tip and the first half inch above the die tip. The temperature then actually increases for about an inch and then falls off to a net drop of about 100 degrees Celsius at five inches above the die tip. The increase in temperature is believed to be due to the use of the second stage heat source. With apparatus C, providing the data for FIG. 8, the initial drop in the first half inch is less than 20 degrees and the total drop over the first six inches is less than 80 degrees. There is also a much smaller or negligible increase in temperature as the ribbon moves from the one half inch level to the two inch level. Apparatus B exhibits a temperature gradient of about 20° C. per inch over the range of 2 inches to 6 inches. Apparatus C however shows a temperature gradient of about 14° C. per inch in the corresponding region.

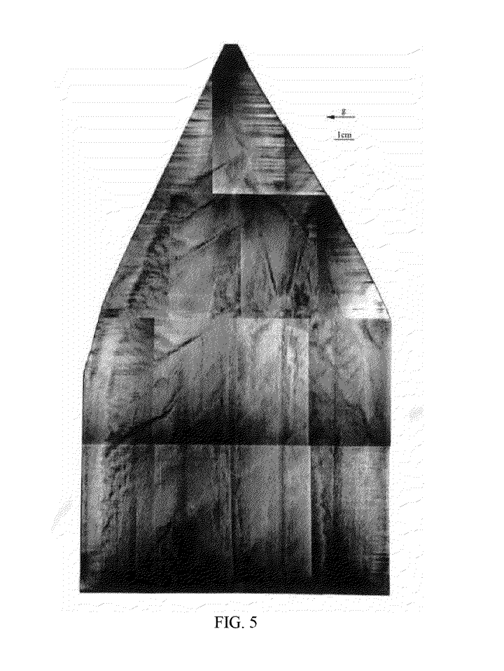

The profile of FIG. 7 has been used to produce the 6 inch wide r-plane ribbon shown in the x-ray topograph of FIG. 4. Extensive lineage is apparent in the topograph. This is in contrast to the topograph of FIG. 5 that is of a 6 inch wide r-plane ribbon grown using the gradient profile of FIG. 8 and shows an absence of lineage. It is believed that these lower temperature gradients may reduce stress within the ribbon and help to reduce slip and to provide a reduced lineage or a lineage free plate.

In one aspect, a method is provided to grow lineage-free r-plane sapphire ribbons. In one embodiment of the method, using the apparatus provided in FIG. 3, a melt of Al₂O₃ is provided by charging crucible 110 with alumina and heating to 2060° C. using inductively coupled heating coil 150. A seed of sapphire is placed at the opening of each die tip so that the r-plane [1-102] is facing left (or right) in FIG. 3. The seed is contacted with the melt on top of the die tip and is pulled upwardly to start the spread. The direction of the draw is in the same direction as the direction [1-10-1] of the crystal. The seed can then be drawn upwardly at an appropriate rate, such as about 1 inch per hour, about 0.5 inches per hour, about 2 inches per hour or greater than 2 inches per hour.

In known EFG methods, the spread is typically formed at a maximum rate, i.e. a maximum rate of weight gain until full width is achieved. This reduces the amount of time needed to get to full width and reduces the amount of less valuable crystal material (because of smaller width) that forms during the spread. To measure the amount of weight gain the support holding the seed is connected to a load cell that is capable of measuring the weight of the ribbon at any interval chosen by the operator. For instance, the weight can be measured and recorded every second. At a constant draw rate it can be seen that as the spread gets larger, the rate of weight gain will increase until full width is obtained.

In general, a colder temperature at the die tip leads to faster crystallization and therefore a faster rate of weight gain as well as a shorter spread that reaches full width more quickly. However, if the temperature at the die top (melt interface) is too low, the melt will crystallize in contact with the die, resulting in a failed ribbon. As the spread gets larger, a greater amount of heat is lost from the developing ribbon, resulting in a lower temperature at the melt interface. To compensate, additional power can be supplied from RF coil 150 to maintain the temperature at the melt interface.

To maximize the spread rate without freezing to the die, the following procedure has been developed and used successfully on a-plane defect-free single crystal sapphire. Heat is measured indirectly using a pyrometer set to take temperature readings on the crucible lid near the die tips. First, the melt is set at a temperature of greater than 2053 degrees Celsius and the seed is contacted with the melt at the melt interface. Once crystallization starts, the draw is started at a rate that is appropriate for the specific ribbon being drawn. The weight gain of the spread is monitored frequently, e.g., every second. As the spread gets larger and causes additional cooling to occur at the die tip, the load cell can detect a weight gain spike that may be due to a viscosity increase in the melt that occurs as crystallization gets close to the die surface. When the controller detects this sudden increase in load (over the course of one to ten seconds) it increases the power to RF coil 150 until the temperature at the pyrometer is raised by one degree Celsius and then maintains this setting until another sudden load increase is detected. When an increase is again detected, the process is repeated and the temperature is raised by one degree Celsius. In this manner, the ribbon can be spread at the maximum rate without damaging the ribbon and without introducing defects. It is believed that when this procedure is followed, the rate of weight gain during the spread is at its maximum at any point during the growth period and this rate of increase is referred to as the “maximum rate of weight gain.” If this rate of weight gain is exceeded it will likely result in a failed ribbon due to crystallization in contact with the die.

The maximum rate of weight gain can be used to produce a-plane sapphire, but it has been shown that r-plane ribbons produced using this method of spread formation result in lineage even though the ribbons appear to the naked eye to be defect free. It has further been discovered that r-plane material benefits from a warmer spread phase and that if the rate of weight gain is kept below the maximum rate of weight gain, that an r-plane ribbon free of lineage can be produced.

Instead of forming the spread at the maximum rate of weight gain it has been found that forming the spread at less than 90%, less than 80% or less than 70% of the maximum rate can result in ribbons, and therefore wafers, that are free of lineage. The rate of weight gain at the beginning of the spread should generally be disregarded because, as a percentage, it can be variable when the width of the ribbon is very small. Typically the first half inch of spread formation is not used to calculate the rate of weight gain and, unless otherwise specified, the first half inch of width of the spread is to be disregarded herein when considering rates of weight gain.

An r-plane sapphire plate is considered to be free of lineage if no lineage can be seen using x-ray topography. An r-plane plate may still be lineage free even though features such as polycrystallinity and dislocations are present. An x-ray topograph of a ribbon showing lineage is provided in FIG. 4. As is typically found the lineage is centrally located throughout a majority of the length of the ribbon. An x-ray topograph of a lineage-free ribbon is provided FIG. 5.

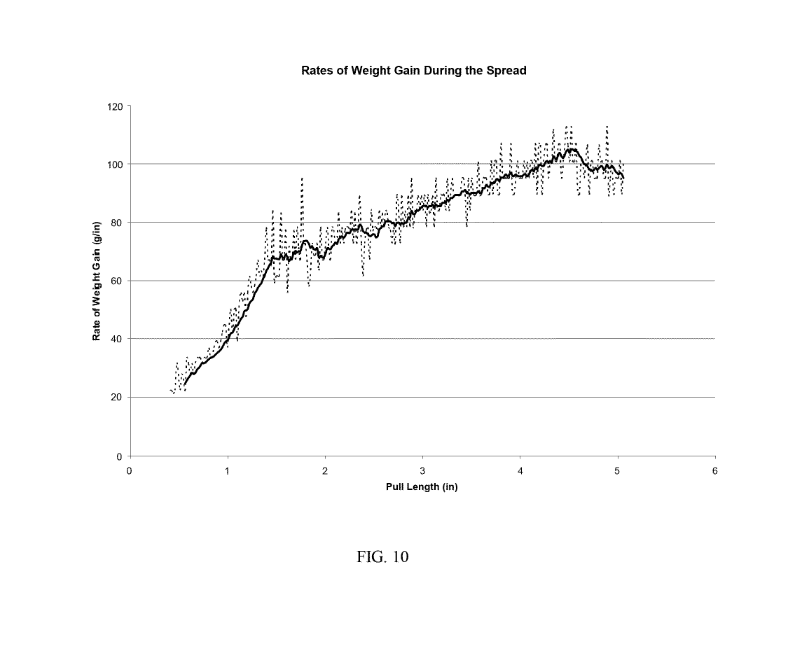

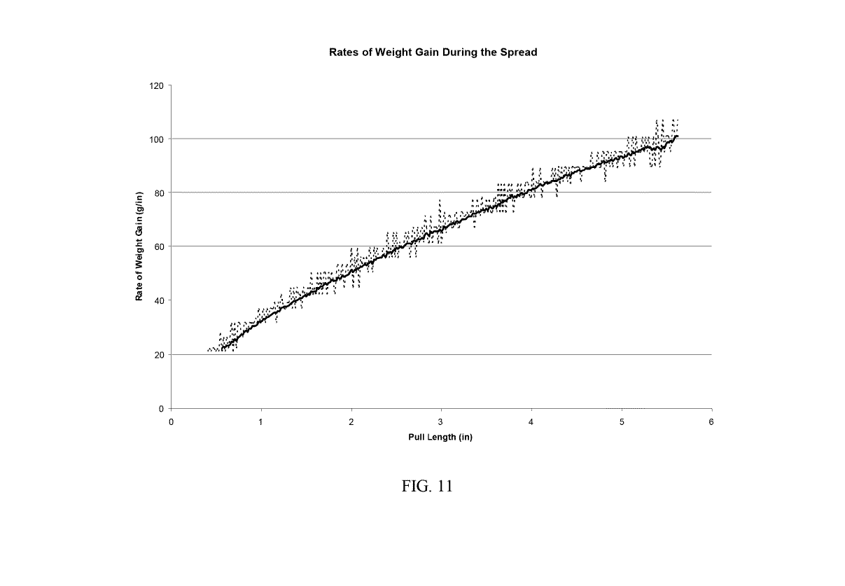

Two graphs showing rate of weight gain vs. pull length are provided in FIGS. 10 and 11. FIG. 10 illustrates the rate of maximum weight gain as described above. FIG. 11 illustrates a controlled rate of weight gain where the rate of weight gain is maintained below 80% of the maximum rate. Both sets of data were generated at a pull rate of 1 inch per hour. The smooth curve of FIG. 11 can be fit to the exponential equation y=ax^{b} where y is the rate of weight gain, x is the pull length and coefficients a and b combine to control the length and angle of the spread. Preferably the data fit this exponential equation and exhibit an r² value of greater than 0.95 or greater than 0.97 using least squares regression analysis. This high r² value indicates a smooth rate of growth with a minimum of jumps or dips in the increase in rate of weight gain. In one embodiment, the target rate of weight gain for producing lineage free r-plane material is y=32x^{0.65}. Rather than fitting an exponential function, the data in the curve showing a maximum rate of growth (FIG. 10) are best modeled using a logarithmic equation, y=34 ln(x)+48.

In other embodiments, the rate of weight gain of the spread may be limited in relation to the rate of weight gain in a previous portion of the spread. For instance, the rate of weight gain during a one inch gain in length may be, for example, not more than 150%, not more than 200% or not more than 250% of the rate of weight gain during any previous one inch length of growth in the same ribbon.

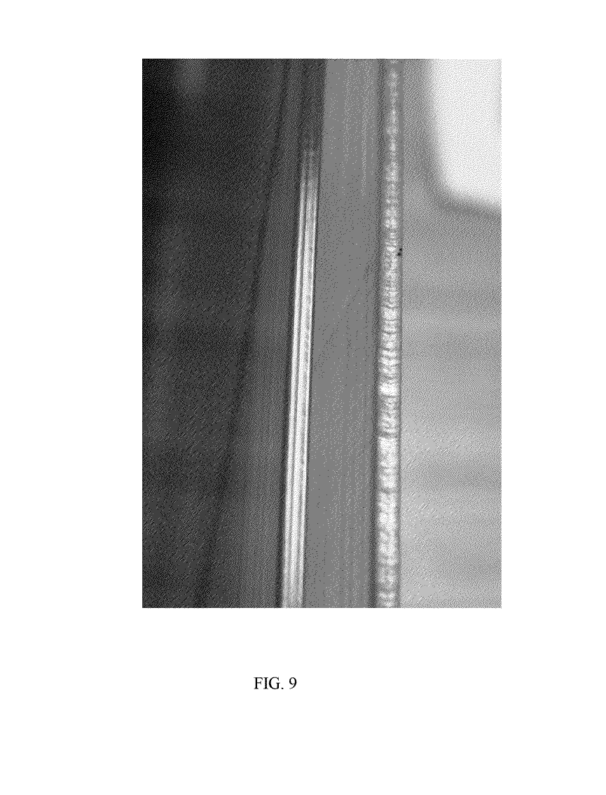

A comparison of ribbons with lineage and those without is difficult with the naked eye. However, another effect of a controlled rate of weight gain can be seen visually and is illustrated in FIG. 9 which shows the edge of an r-plane ribbon grown at the maximum rate of weight gain (right side of FIG. 9) and at a controlled rate of weight gain that is less than 80% of the maximum rate of weight gain (left side of FIG. 9). It is apparent that a much smoother edge (left side of FIG. 9) develops when the more controlled rate of weight gain is used. Although edge quality is not typically monitored because many end products are cut from the ribbons, the smoother edge may indicate less stress that may result in less slip and/or less lineage.

In another aspect, r-plane single crystal sapphire can be produced using EFG techniques that control the rate of cooling of the crystallized ribbon. In one set of embodiments this may include two distinct zones of cooling. Known systems that are used to produce single crystal sapphire by EFG methods typically use vertical temperature gradients of greater than 100° C. per inch in the region directly downstream of the melt interface. This means that as a point on the sapphire ribbon advances one inch downstream (usually vertically up) from point a to point b that the temperature at point b will be 100° C. lower than when it was at point a. This also means that the ribbon will cool by about 100° C. as it is drawn one inch upward, and, if drawn at one inch per hour, it will take about one hour to do so. As ribbon temperatures are difficult to measure directly during production, these values are usually interpolated from temperature measurements taken without the ribbons present.

At temperatures above about 1850° C. it has been determined that control of the cooling rate of a sapphire crystal may affect its crystalline quality. For example, if cooled too quickly, “slip” of one crystal plane over another may occur and may lead to lineage. Another type of crystalline defect that may be controlled by regulated cooling is dislocations. Once the temperature of the crystal drops below about 1850° C. it may be of a more stable single crystal structure and the rate of cooling may not need to be regulated as carefully. For instance, if the crystal exits the apparatus below its brittle-ductile transition point, it may be allowed to cool to room temperature at a rapid rate without any irreversible damage to the crystal.

Thermal gradients may be varied at any specific location in the apparatus although once ribbon production has started it may be preferred that gradients are maintained at constant values. However, gradients may be adjusted during production to compensate for variations in process parameters or to improve ribbon quality. Thermal gradients may be controlled by, for example, lowering or raising heat shields, adding or removing insulation, reducing the size of view ports, adding a door to the chimney portion of the apparatus, and/or actively heating or cooling a portion or portions of the apparatus.

Thermal gradients may be substantially constant over the length of the gradient. For instance, a thermal gradient may be substantially constant over a distance of less than one half inch, greater than one half inch, greater than one inch, greater than 1.5 inches, greater than two inches, greater than 4 inches, greater than 6 inches or greater than 8 inches. Thermal gradients may also vary over the length of the gradient, particularly at the beginning and/or end of the gradient. Of course, when moving from one gradient to another there may be a transition distance over which the gradient will shift from the first to the second gradient. Unless otherwise specified, a thermal gradient for a specific region is the average thermal gradient throughout the region.

Cooling may also be controlled for a length of time rather than for a specific pull length. For instance, for the first hour of formation after crystallization the decrease in temperature may be limited to less than 80° C., less than 60° C., less than 40° C. or less than 30° C. For the first six hours of formation the decrease in temperature may be limited to, for example, less than 120° C., less than 100° C. or less than 80° C. During the time period from 2 hours to 8 hours after crystallization the decrease in temperature may be limited to, for example, less than 140° C., less than 120° C. or less than 100° C.

The apparatus of FIG. 3 includes two distinct cooling regions, Z₁ and Z₂, that can be used to control the rate of cooling. Region Z₂ includes an independent heater that can actively supply heat to the region. In the embodiment shown, inductive heating coils 152 are coupled with molybdenum enclosure 142 to actively add heat to the region. This helps to compensate for heat lost from the ribbons to the outside environment. It has been found that a substantial portion of the heat is lost through radiation that is guided by the ribbons themselves. Much of this heat can be retained by the use of door 160 and it has also been shown that a reduction in the size of the two viewports (not shown) can also reduce heat loss. Door 160 may also aid in reducing the amount of heat lost due to convection of the inert gas flow along the surfaces of enclosure 142. With the implementation of these changes, the temperature gradient in region Z₂ can be controlled to be less than 20° C. per inch, less than 18° C. per inch, less than 16° C. per inch or less than 14° C. per inch. Similarly, the temperature gradient in zone Z₁, which is typically the hotter of the two zones, can also be controlled to provide a gradient that is less than conventional EFG gradients. This control can be accomplished, at least in part, through the implementation of smaller viewports, the installation of door 160, the use of heat shields 140 and by staggering the heights of outer die tips 122 in relation to inner die tip 124. Favorable temperature gradients that can be achieved in zone Z₁, adjacent to the melt interface, are less than 100° C. per inch, less than 80° C. per inch, less than 60° C. per inch or less than 40° C. per inch.

### EXAMPLE

A six inch wide, 18 inch long r-plane single crystal sapphire ribbon showing no detectable lineage was grown with the following method.

Using the crystal growth apparatus of FIG. 3, a sapphire seed was placed in contact with an alumina melt on the top surface of the respective die tips. The seed was oriented with face [1-102] aligned with the width (long horizontal dimension) of the die opening and was pulled vertically in the [1-10-1] direction. As crystallization proceeded, the seed was drawn upwardly at a rate of one inch per hour. A program of controlled weight gain was implemented to produce a warm spread and the controlled rate of weight gain was kept below 80% of the maximum rate of weight gain. The rate of weight gain is shown in FIG. 11 and fits the equation y=32x^{0.65} with an r² value of 0.96. Full ribbon width was achieved after about 6 inches of pull length.

The apparatus was operated to reproduce the temperature profile shown in FIG. 8. As the ribbon was pulled through region Z1 of the apparatus, the vertical temperature gradient (at center) was maintained at less than about 40° C. per inch, getting progressively cooler in the upward direction. Between regions Z1 and Z2 there is a transition zone where the temperature gradient decreases from the gradient of region Z1 to the average 14° C. per inch gradient of region Z2. Throughout Z1 and Z2 the temperature of the ribbons was maintained at greater than about 1850° C. A low rate of cooling is sustainable, at least in part, through the use of smaller viewports, active heating and insulating door 160.

The pull rate of 1 inch per hour was maintained until an 18 inch long ribbon was obtained. The growth speed was then increased until the crystal separated from the die. The ribbon was then moved slowly up to and removed through opening 162 by opening trap door 160 and was allowed to finish cooling to room temperature. Once the material has cooled to below the brittle-ductile transition point it may be subjected to an uncontrolled rate of cooling although some control may still be desirable. An x-ray topograph of a portion of the ribbon is shown in FIG. 5 and indicates an absence of lineage.

While several embodiments of the present invention have been described and illustrated herein, those of ordinary skill in the art will readily envision a variety of other means and/or structures for performing the functions and/or obtaining the results and/or one or more of the advantages described herein, and each of such variations and/or modifications is deemed to be within the scope of the present invention. More generally, those skilled in the art will readily appreciate that all parameters, dimensions, materials, and configurations described herein are meant to be exemplary and that the actual parameters, dimensions, materials, and/or configurations will depend upon the specific application or applications for which the teachings of the present invention is/are used. Those skilled in the art will recognize, or be able to ascertain using no more than routine experimentation, many equivalents to the specific embodiments of the invention described herein. It is, therefore, to be understood that the foregoing embodiments are presented by way of example only and that, within the scope of the appended claims and equivalents thereto, the invention may be practiced otherwise than as specifically described and claimed. The present invention is directed to each individual feature, system, article, material, kit, and/or method described herein. In addition, any combination of two or more such features, systems, articles, materials, kits, and/or methods, if such features, systems, articles, materials, kits, and/or methods are not mutually inconsistent, is included within the scope of the present invention.

All definitions, as defined and used herein, should be understood to control over dictionary definitions, definitions in documents incorporated by reference, and/or ordinary meanings of the defined terms.

The indefinite articles “a” and “an,” as used herein in the specification and in the claims, unless clearly indicated to the contrary, should be understood to mean “at least one.”

All references, patents and patent applications and publications that are cited or referred to in this application are incorporated in their entirety herein by reference.

What is claimed is:

1. A method of forming an r-plane single crystal sapphire ribbon comprising:
seeding a crystal melt in an r-plane orientation;
pulling the seed to form a spread; and
controlling a weight gain of the crystal during a time period from when a spread increases in width from 0.5 inch to a full width by limiting a rate of weight gain during any 1 inch pull length increment to less than double the rate of weight gain for the previous 1 inch pull length increment.

2. The method of claim 1, wherein the rate of weight gain is controlled by adjusting a temperature of the melt.

3. The method of claim 1, further comprising:
passing the r-plane single crystal sapphire ribbon through a first region exhibiting a first thermal gradient of less than 65° C./in; and
subsequently passing the r-plane single crystal sapphire ribbon through a second region exhibiting a second thermal gradient of less than 20° C./in wherein the first region is adjacent a die tip and has a length of less than about one half inch, and the second region is adjacent to the first region and has a length of at least one inch and less than 6 inches.

4. The method of claim 3, wherein a temperature of a center of the r-plane single crystal sapphire ribbon does not drop below 1850° C. prior to exiting the second region.

5. The method of claim 1, wherein an orientation of a major surface of the r-plane single crystal sapphire ribbon is less than two degrees from [1-102].

6. A method of forming an r-plane single crystal sapphire ribbon comprising:
seeding a crystal melt in an r-plane orientation;
pulling the seed to form the spread; and
controlling a weight gain of the crystal during a time period from when a spread increases in width from 0.5 inch to a full width by limiting a rate of weight gain to less than 90% of a maximum weight gain rate.

7. The method of claim 6, wherein the rate of weight gain is less than 80% of the maximum weight gain rate.

8. The method of claim 6, wherein the rate of weight gain is less than 70% of the maximum weight gain rate.

9. The method of claim 6, wherein the r-plane single crystal sapphire ribbon has a width of at least 150 mm and exhibits no detectable lineage when using x-ray topography.

10. The method of claim 6, further comprising cutting the r-plane single crystal sapphire ribbon to form a wafer having a diameter of at least 200 mm.

11. The method of claim 10, wherein the wafer exhibits no detectable lineage when using x-ray topography.

12. The method of claim 6, wherein the r-plane single crystal sapphire ribbon is formed using an edge defined film-fed growth technique.

13. The method of claim 6, further comprising cooling the r-plane single crystal sapphire ribbon, such that a decrease in temperature during a first hour is less than 80° C.

14. The method of claim 6, further comprising cooling the r-plane single crystal sapphire ribbon, such that a decrease in temperature during a time period from 2 hours to 8 hours is less than 140° C.

15. The method of claim 6, further comprising:
passing the r-plane single crystal sapphire ribbon through a first region exhibiting a first thermal gradient of less than 65° C./in; and
subsequently passing the r-plane single crystal sapphire ribbon through a second region exhibiting a second thermal gradient of less than 20° C./in wherein the first region is adjacent a die tip and has a length of less than about one half inch and the second region is adjacent to the first region and has a length of at least one inch and less than 6 inches.

16. The method of claim 15, wherein a temperature of a center of the r-plane single crystal sapphire ribbon does not drop below 1850° C. prior to exiting the second region.

17. The method of claim 6, further comprising forming the single crystal sapphire wherein an orientation of a major surface of the sapphire is less than two degrees from [1-102].

18. An as-formed r-plane single crystal sapphire ribbon having a neck and a body with substantially planar major surfaces, a width of greater than or equal to 150 mm, and exhibiting no detectable lineage using x-ray topography, wherein the ribbon is formed using a shaped crystal growth technique.

19. The as-formed r-plane single crystal sapphire ribbon of claim 18 having a length of greater than 250 mm measuring from the neck.

20. The as-formed r-plane single crystal sapphire ribbon of claim 18, wherein the major surfaces are less than two degrees from [1-102].
